(19) United States
(12) Patent Application Publication
(10) Pub. No.: US 2010/0091168 A1
(43) Pub. Date: Apr. 15, 2010

(54) SOLID-STATE IMAGE PICKUP APPARATUS, AND METHOD OF MANUFACTURING SOLID-STATE IMAGE PICKUP APPARATUS

(75) Inventors: Takatoshi IGARASHI, Kamiina-gun (JP); Noriyuki FUJIMORI, Suwa-shi (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 12/575,045

(22) Filed: Oct. 7, 2009

(30) Foreign Application Priority Data
Oct. 15, 2008 (JP) 2008-266658

(51) Int. Cl. H04N 5/225; H01L 31/18

(52) U.S. Cl. 348/340; 438/69; 348/E05.024; 257/E21.211; 257/E31.127

(57) ABSTRACT

A solid-state image pickup apparatus includes a solid-state image pickup device, a microlens member laminated on the solid-state image pickup device, and a flat plate-like cover glass attached onto a region excluding a pixel region on the microlens member as viewed in a planar manner from above the microlens member to seal the pixel region of the solid-state image pickup device.

### CROSS REFERENCE TO RELATED APPLICATION

This application claims the benefit of Japanese Application No. 2008-266658 filed in Japan on Oct. 15, 2008, the contents of which are incorporated herein by this reference.

### BACKGROUND OF THE INVENTION

1. Field of the Invention

The present invention relates to a solid-state image pickup apparatus, and a method of manufacturing the solid-state image pickup apparatus.

2. Description of the Related Art

Conventionally, there have been known an electronic endoscope, a camera-equipped cell phone, a digital camera or the like including a solid-state image pickup apparatus in which a solid-state image pickup device such as CCD or CMOS is provided. A solid-state image pickup apparatus of a wafer level chip size package (referred to as “WL-CSP” below) type has been recently known as the solid-state image pickup apparatus. In the WL-CSP type solid-state image pickup apparatus, packaging of the solid-state image pickup apparatus is completed by attaching a cover glass wafer onto a sensor wafer on which a plurality of solid-state image pickup devices are formed at a wafer level, and separating the solid-state image pickup devices into individual chips by dicing.

In order to obtain a sufficient light-focusing effect of a convex-shaped microlens provided on a pixel region of a solid-state image pickup device, it is necessary to form an air gap between the microlens and a cover glass at the time of manufacturing the WL-CSP type solid-state image pickup apparatus. Japanese Patent No. 3880278 discloses a configuration in which a spacer having an opening formed in a pixel region is interposed between a solid-state image pickup device and a cover glass to obtain an air gap. To be more specific, Japanese Patent No. 3880278 discloses a solid-state image pickup apparatus 200 as shown in FIG. 1. In the solid-state image pickup apparatus 200, an epoxy-type resin sheet (the spacer) 202 in which an opening portion 202h is formed in a portion corresponding to a pixel region on which a microlens 204 of a solid-state image pickup device 201 is formed is adhered onto the solid-state image pickup device 201 by an adhesive 205. A flat-plate portion 203 formed of a transparent member is adhered onto the epoxy-type resin sheet 202 by the adhesive 205 so as to seal the pixel region. The opening portion 202h functions as an air gap.

A plurality of solid-state image pickup apparatuses 200 can be formed at once by forming the microlens 204 on each of the solid-state image pickup devices 201 of a sensor wafer, adhering thereto the epoxy-type resin sheet having the opening portions 202h formed in the pixel regions and having substantially a same size as that of the sensor wafer, adhering the flat-plate portion having substantially a same size as that of the epoxy-type resin sheet and formed of the transparent member onto the epoxy-type resin sheet to seal each of the opening portions 202h, and collectively dicing the sensor wafer, the epoxy-type resin sheet, and the flat-plate portion.

According to the configuration of the solid-state image pickup apparatus 200 and the method of manufacture thereof, smaller size packaging of the solid-state image pickup apparatus can be achieved. Also, since the air gap can be reliably formed in the pixel region on which the convex-shaped microlens is formed, the light-focusing effect of the microlens is not degraded.

In the method of manufacturing the solid-state image pickup apparatus disclosed in Japanese Patent No. 3880278, however, a process of interposing the spacer between the solid-state image pickup device and the flat-plate portion is required to form the air gap, thereby increasing the number of manufacturing processes.

### SUMMARY OF THE INVENTION

A solid-state image pickup apparatus according to an embodiment of the present invention includes: a solid-state image pickup device; a microlens member laminated on the solid-state image pickup device; and a flat plate-like transparent member attached onto at least a portion of the microlens member as viewed in a planar manner from above the microlens member to seal a pixel region of the solid-state image pickup device.

### BRIEF DESCRIPTION OF THE DRAWINGS

FIG. 1 is a sectional view schematically illustrating a configuration of a conventional solid-state image pickup apparatus;

FIG. 2 is a top view of a solid-state image pickup apparatus according to a first embodiment;

FIG. 3 is a sectional view of the solid-state image pickup apparatus taken along a line III-III in FIG. 2;

FIG. 4 is an exploded perspective view of the solid-state image pickup apparatus according to the first embodiment;

FIGS. 5A to 5F are sectional views for explaining processes for manufacturing the solid-state image pickup apparatus according to the first embodiment;

FIG. 6 is a perspective view illustrating a state in which diffractive lenses are formed in circular shapes on a pixel region of a solid-state image pickup device in a solid-state image pickup apparatus according to a second embodiment;

FIG. 7 is a sectional view of the solid-state image pickup apparatus according to the second embodiment;

FIG. 8 is a sectional view illustrating an enlarged portion of the pixel region of the solid-state image pickup apparatus according to the second embodiment;

FIGS. 9A to 9F are sectional views for explaining processes for manufacturing the solid-state image pickup apparatus according to the second embodiment; and

FIG. 10 is a view illustrating an endoscope apparatus including an endoscope in which a solid-state image pickup apparatus according to an embodiment is provided.

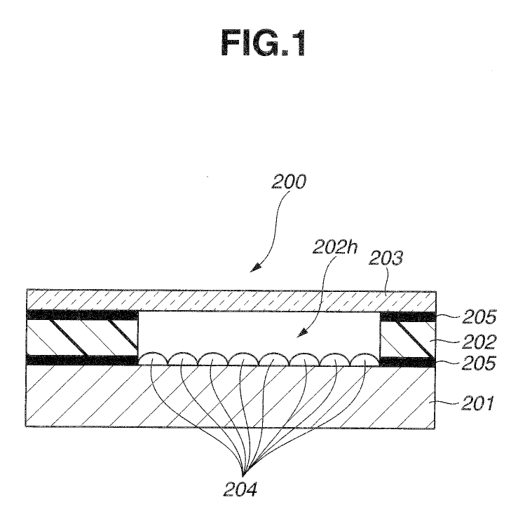

### DETAILED DESCRIPTION OF THE PREFERRED EMBODIMENTS

In the following, a solid-state image pickup apparatus or the like according to embodiments of the present invention will be described with reference to the drawings. Note that the drawings are schematic representations and a relationship between a thickness and a width of each member, a thickness ratio of respective members or the like may be different from those actually measured. Needless to say, a relationship or a ratio of dimensions may be different in each of the drawings.

### First Embodiment

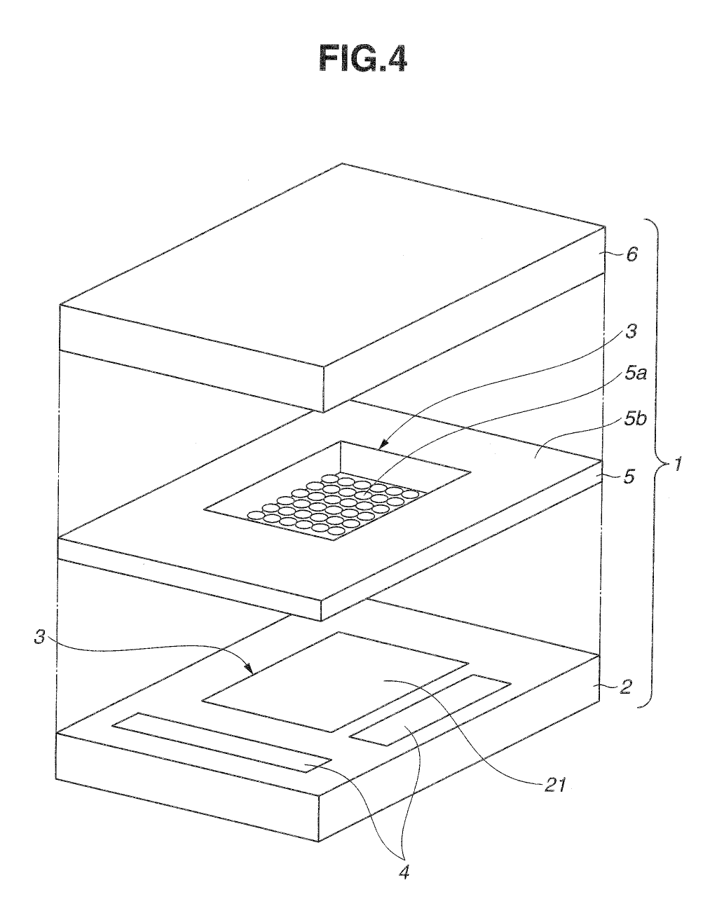

A solid-state image pickup apparatus according to a first embodiment of the present invention will be described below. As shown in FIGS. 3 and 4, a solid-state image pickup device 2, a microlens member 5 made of a transparent resin material, and a cover glass 6 that is a flat plate-like transparent member constitute a main portion of a solid-state image pickup apparatus 1 of the present embodiment. A plurality of light receiving portions 21 are formed in a pixel region 3 arranged at a center portion of the solid-state image pickup device 2.

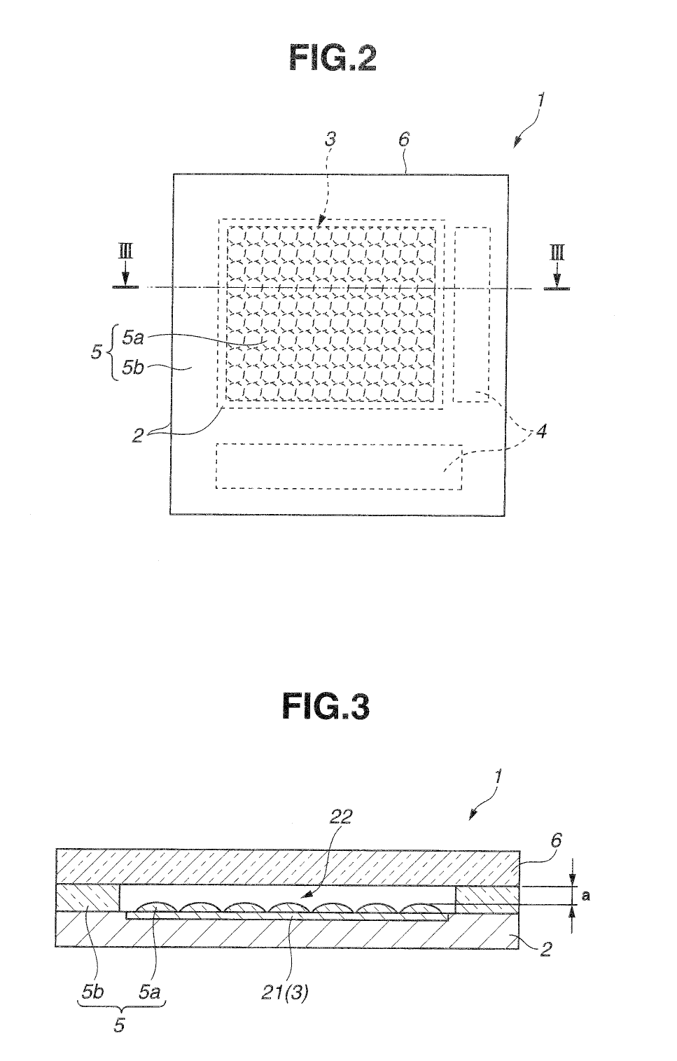

As shown in FIGS. 2 to 4, the microlens member 5 is laminated on the solid-state image pickup device 2. The microlens member 5 includes a lens-shaped portion 5a that functions as a microlens on the pixel region 3, that is, on each of the light receiving portions 21 as viewed in a planar manner from above. The “above” means an upper side in FIG. 4 or the like, that is, the cover glass 6 side. A microlens-shaped portion 5a including a microlens group having convex-shaped microlenses respectively corresponding to the light receiving portions 21 is arranged in a center region of the microlens member 5. A portion 5b laminated in a frame shape on a region around the pixel region 3 has a flat plate shape. The microlens-shaped portion 5a and the portion 5b are made of the same transparent resin material.

As shown in FIGS. 3 and 4, the lens-shaped portion 5a is formed lower by a length a than the region excluding the pixel region 3 as viewed in a planar manner from above the microlens member 5, that is, the portion 5b laminated on the region including peripheral circuits 4 such as a shift register, an AD converter, and an output amplifier toward the solid-state image pickup device 2. In other words, a maximum thickness of the microlens-shaped portion 5a of the microlens member 5 is smaller than a thickness of the portion 5b.

The cover glass 6 is attached onto the microlens member 5 such that the cover glass 6 is bonded to at least a portion of the microlens member 5, more specifically, the portion 5b on the region excluding the pixel region 3. The cover glass 6 thereby seals the pixel region 3 of the solid-state image pickup device 2. The cover glass 6 is bonded onto the portion 5b of the microlens member 5 by an optically transparent adhesive that is uniformly applied on the cover glass 6 by spin coating. Alternatively, the resin itself as the material of the microlens member 5 may function as an adhesive to be used for the bonding of the cover glass 6.

The cover glass 6 may be also bonded onto the portion 5b of the microlens member 5 by applying an adhesive on the portion 5b by screen printing or dispensing. Furthermore, the cover glass 6 may be also bonded onto the portion 5b by local melting caused by irradiation of focused femtosecond laser pulses onto an interface between the cover glass 6 and the microlens member 5.

Since the lens-shaped portion 5a of the microlens member 5 is formed lower by the length a than the portion 5b toward the solid-state image pickup device 2, an air gap 22 as a gap is formed between the microlens member 5 and the cover glass 6 in the pixel region 3. The air gap 22 maintains a light-focusing effect of the lens-shaped portion 5a even after the cover glass 6 seals the pixel region 3.

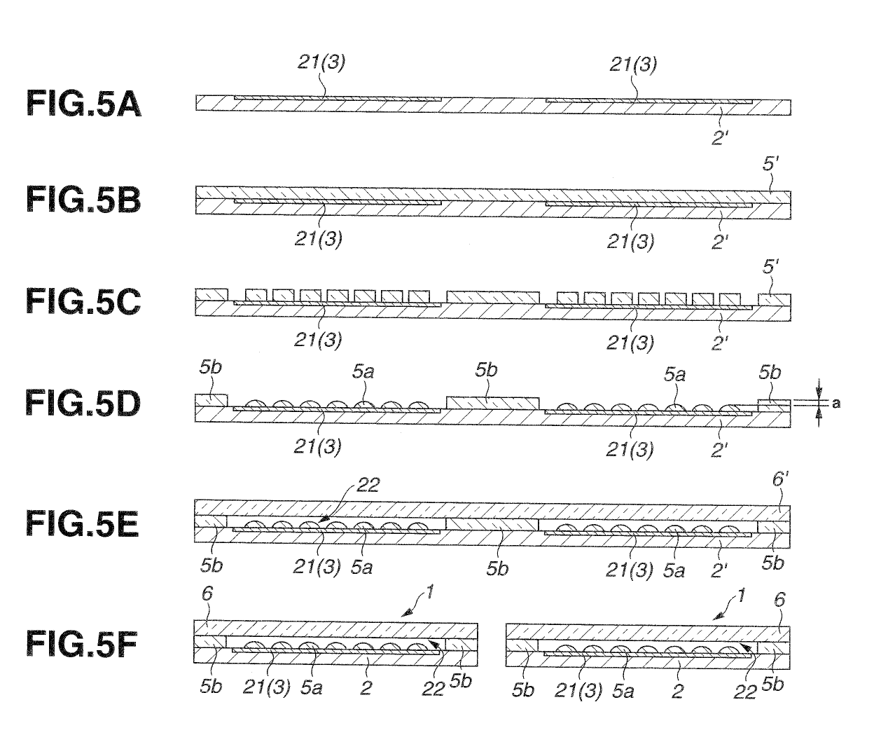

Next, a method of manufacturing the solid-state image pickup apparatus 1 will be described by using FIGS. 5A to 5F. FIGS. 5A to 5F are partial sectional views of a region including two solid-state image pickup apparatuses for explaining processes for manufacturing the solid-state image pickup apparatus shown in FIG. 2. FIG. 5A is a sectional view illustrating a sensor wafer. FIG. 5B is a sectional view illustrating a state in which a microlens material is laminated on the sensor wafer in FIG. 5A. FIG. 5C is a sectional view illustrating a state in which pixel regions of the microlens material in FIG. 5B are patterned. FIG. 5D is a sectional view illustrating a state in which portions obtained by patterning the microlens material in FIG. 5C are formed into lens-shaped portions. FIG. 5E is a sectional view illustrating a state in which a cover glass wafer is attached onto the microlens material in FIG. 5D. FIG. 5F is a sectional view illustrating a state in which a structure in FIG. 5E is divided to manufacture a plurality of solid-state image pickup apparatuses.

First, a manufacturer prepares a sensor wafer 2′ where a photodiode and a color filter are formed on each of the light receiving portions 21 of the pixel region 3 as shown in FIG. 5A. Subsequently, the manufacturer applies, that is, laminates a microlens material 5′ made of a thermosetting light-transmissive resin on the sensor wafer 2′ by use of a method such as spin coating such that the microlens material 5′ has a uniform thickness in a process of laminating a microlens member as shown in FIG. 5B.

Subsequently, the manufacturer forms the portions to be the lens-shaped portions 5a by patterning the microlens material 5′ on each of the pixel regions 3 by use of a method such as photolithography in a process of forming a lens-shaped portion as shown in FIG. 5C.

The manufacturer then performs a heat curing treatment to deform the patterned portions of the microlens material 5′ to respectively become the lens-shaped portions 5a in the process of forming a lens-shaped portion as shown in FIG. 5D. Each of the portions is thereby rounded with its edges being removed, so that the lens-shaped portion 5a having a substantially hemispherical shape, that is, the convex-shaped microlens is formed. At this point, in the microlens material 5′, each of the lens-shaped portions 5a is formed lower by the length a than the portion 5b of the microlens material 5′ which is not patterned toward the sensor wafer 2′ due to the deformation by heating. Although not shown in the drawings, edges of the portion 5b of the microlens material 5′ other than the pixel region 3 are also rounded by the heat treatment. However, a height of a resin layer in the portion 5b is maintained. Since the portions to be the lens-shaped portions 5a are isolated patterns each having a small area, the portions are deformed larger than the portion 5b having a large area other than the pixel region 3.

A difference in height a between each of the lens-shaped portions 5a and the portion 5b, that is, a height of the air gap 22 may have any length as long as interference fringes are hidden after attaching a cover glass wafer 6′ described below. To be more specific, the difference in height a, that is, the height of the air gap 22 may be 1 μm or more.

Recently, an insulating film on the pixel region tends to be made thinner than an insulating film on the peripheral circuits in order not to degrade the light-focusing effect of the microlens even when pixel dimensions are reduced. Therefore, the difference in height a is becoming easy to obtain.

In order to further increase the difference in height a, a microlens material layer may be laminated by spin-coating the microlens material again on the region other than the pixel region 3 by use of a method such as photolithography to increase a thickness of the region between the processes in FIGS. 5D and 5E.

In the sensor wafer 2′ shown in FIG. 5A obtained before applying the resin constituting the microlens material 5′, each of the light receiving portions 21 may be higher than the peripheral region in some cases. In such cases, a process of flattening a surface of the applied microlens material 5′ may be added after applying the resin constituting the microlens material 5′.

A color filter having one layer of any one of red (R), green (G), and blue (B) is formed on each pixel on each of the light receiving portions 21. Therefore, by not removing a color filter having three layers on the region excluding the pixel region 3 at the time of forming the color filter, the region excluding the pixel region 3 can be made higher than the pixel region 3. Accordingly, the air gap 22 can be easily obtained after forming the lens-shaped portions 5a.

Subsequently, the manufacturer attaches the cover glass wafer 6′ onto the microlens member 5 made of the microlens material 5′ such that the cover glass wafer 6′ is bonded onto at least a portion of the microlens member 5 as viewed in a planar manner from above, more specifically, onto the portion 5b of the microlens member 5 in a process of attaching a transparent member as shown in FIG. 5E.

As described above, the cover glass wafer 6′ may be bonded onto the portion 5b of the microlens member 5 by using an optically transparent adhesive applied thinly over an entire surface of the cover glass wafer 6′, or by using an adhesive applied to the portion 5b by a method such as screen printing or dispensing. Alternatively, the resin itself constituting the microlens member 5 may be used as an adhesive. It is preferable to bond the cover glass wafer 6′ onto the portion 5b of the microlens member 5 in a vacuum in order to prevent air bubbles from being formed between bonded surfaces.

Lastly, the manufacturer divides the structure shown in FIG. 5E by dicing to obtain the separate solid-state image pickup apparatuses 1 as shown FIG. 5F.

As described above, in the present embodiment, the portions located in the pixel region 3 of the microlens member 5 laminated between the solid-state image pickup device 2 and the cover glass 6 are formed into the lens-shaped portions 5a that function as the microlenses. The lens-shaped portions 5a are formed lower than the other portion 5b of the microlens member 5 toward the solid-state image pickup device 2. The air gap 22 is thereby formed between the solid-state image pickup device 2 and the cover glass 6 in the pixel region 3.

In the conventional method of manufacturing a solid-state image pickup apparatus described above, it is necessary to separately perform the process of interposing the spacer having the opening portion formed in the pixel region between the solid-state image pickup device and the flat-plate portion to obtain the air gap in the pixel region. Thus, there is a problem that the number of manufacturing processes is increased.

However, in the solid-state image pickup apparatus 1 according to the present embodiment, the air gap 22 can be formed by use of the difference in height a between the lens-shaped portions 5a and the portion 5b in the microlens member 5 without separately forming a spacer. That is, the microlens member 5 itself also functions as a spacer. Therefore, the number of processes for manufacturing the solid-state image pickup apparatus 1 is decreased in comparison with the conventional case.

The region on the peripheral circuits 4 of the solid-state image pickup device 2 is also included in the region where the cover glass 6 is bonded to the microlens member 5. The region on the peripheral circuits 4, that is, the portion 5b has a large bonding area. Thus, even when the solid-state image pickup apparatus 1 is reduced in size, the solid-state image pickup device 2 is improved in reliability since a sufficient bonding strength of the cover glass 6 to the microlens member 5 is obtained.

Accordingly, the solid-state image pickup apparatus having a configuration capable of maintaining the microlens effect on the pixel region without using a spacer, and the method of manufacturing the solid-state image pickup apparatus can be provided.

### Second Embodiment

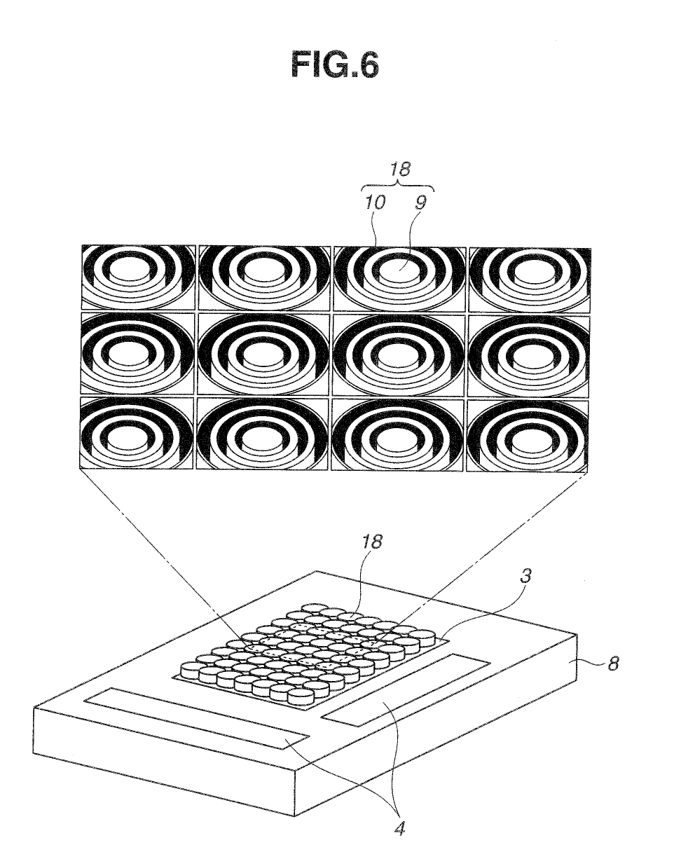

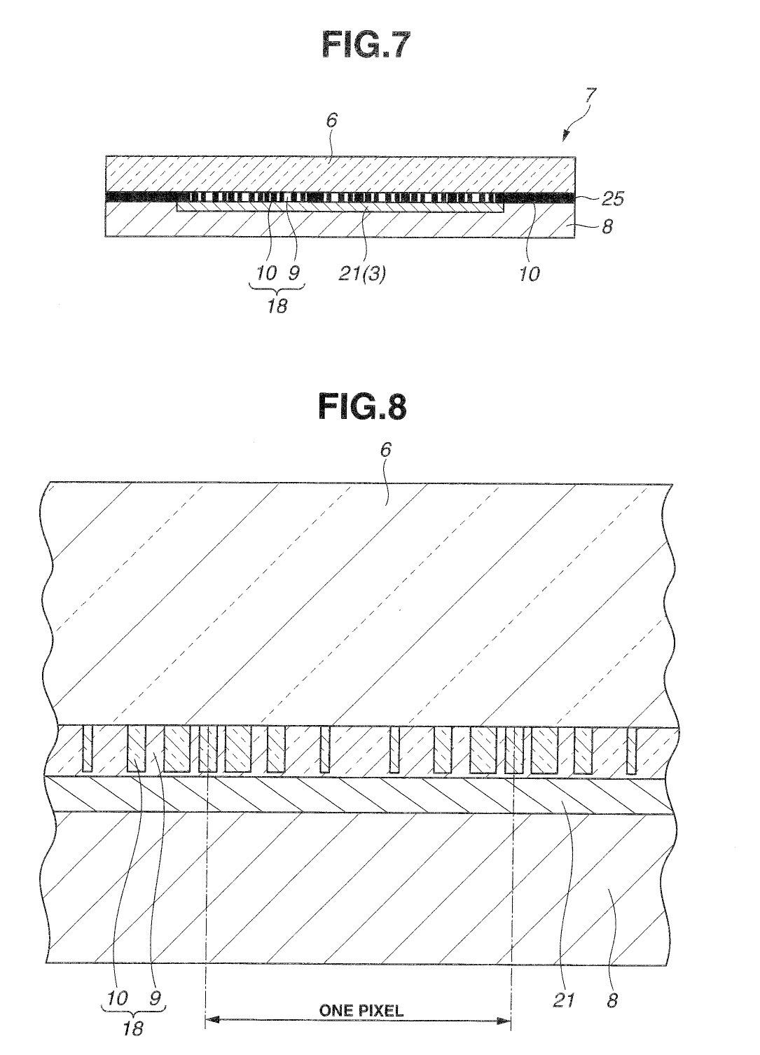

FIG. 6 is a perspective view illustrating a state in which diffractive lenses are formed in circular shapes on a pixel region of a solid-state image pickup device in a solid-state image pickup apparatus according to a present embodiment. FIG. 7 is a partial sectional view illustrating a pixel region in the solid-state image pickup apparatus according to the present embodiment. FIG. 8 is a sectional view illustrating an enlarged portion of the pixel region of the solid-state image pickup apparatus shown in FIG. 7.

A configuration of the solid-state image pickup apparatus according to the second embodiment is different from that of the solid-state image pickup apparatus according to the first embodiment in a configuration of the microlens in which the air gap is not fanned between the solid-state image pickup device and the cover glass. Therefore, only a difference between the first and second embodiments is described, and the same components as those of the first embodiment are assigned the same reference numerals to omit descriptions thereof.

As shown in FIG. 6, a solid-state image pickup device 8 of a solid-state image pickup apparatus 7 according to the present embodiment does not have the convex-shaped microlens but has a diffractive lens 18 as the microlens. That is, the diffractive lens 18 including a high refractive index material 9 as a first photorefractive material patterned in a circular shape, for example, in a concentric shape as viewed in a planar manner from above on the pixel region 3, and a low refractive index resin 10 as a second photorefractive material filled in a gap of the high refractive index material and having a lower refractive index than the high refractive index material as shown in FIGS. 7 and 8 is formed. The low refractive index resin 10 is also laminated on a portion of the solid-state image pickup device 8 excluding the pixel region 3 as shown in FIG. 7. That is, a microlens member 25 including a diffractive lens layer of the high refractive index material 9 and the low refractive index resin 10 is formed on the solid-state image pickup device 8.

in a case where an aspect ratio of a pixel shape is not 1, the diffractive lens 18 may have an elliptical shape in accordance with the aspect ratio of the pixel. The high refractive index material 9 may be any material such as an optically transparent resin and an inorganic material as long as the material has a high refractive index. For example, silicon nitride (Si₃N₄), tantalum pentoxide (Ta₂O₅), or diamond can be used.

As shown in FIGS. 7 and 8, the cover glass 6 is adhered to the microlens member 25 such that the cover glass 6 is bonded onto at least a portion of the microlens member 25, more specifically, an entire surface of the microlens member 25. The low refractive index resin 10 of the microlens member 25 fills the gap of the high refractive index material 9 of the diffractive lens 18, and is also applied on an entire surface of the solid-state image pickup device 8 including the peripheral circuits 4 such as a shift register, an AD converter, and an output amplifier. A large bonding region is thereby obtained, so that a sufficient adhesion strength of the cover glass 6 is obtained.

Although FIG. 8 illustrates a structure in which the diffractive lens 18, that is, the microlens member 25 and the cover glass 6 are directly bonded to each other, a layer of the low refractive index resin 10 may be interposed between the diffractive lens 18 and the cover glass 6. In this case, light entering the solid-state image pickup apparatus 7 through the cover glass 6 is focused by a diffractive action generated between the low refractive index resin 10 and the diffractive lens 18 having a high refractive index, and is received by the light receiving portion 21 formed in the pixel region 3 on the solid-state image pickup device 8. A desired image is thereby obtained.

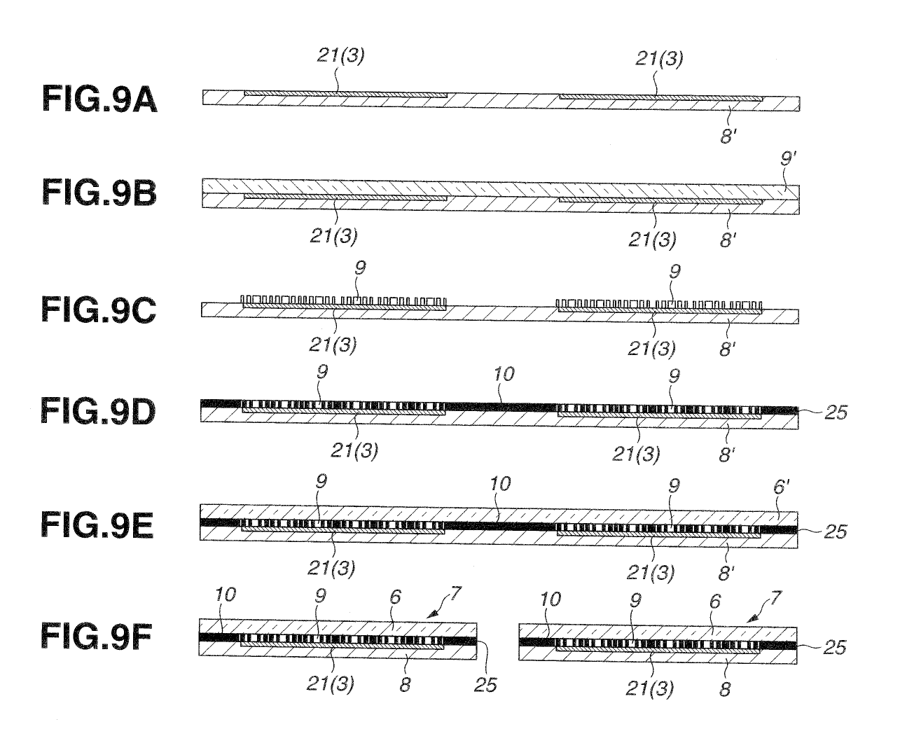

Next, a method of manufacturing the solid-state image pickup apparatus 7 configured as described above will be described by using FIGS. 9A to 9F. FIG. 9 are partial sectional views of a region including two solid-state image pickup apparatuses for explaining processes for manufacturing the solid-state image pickup apparatus shown in FIG. 7. FIG. 9A is a sectional view illustrating a sensor wafer. FIG. 9B is a sectional view illustrating a state in which a high refractive index material is laminated on the sensor wafer in FIG. 9A. FIG. 9C is a sectional view illustrating a state in which the high refractive index material in FIG. 9B located in pixel regions is patterned in a circular shape. FIG. 9D is a sectional view illustrating a state in which a low refractive index material is filled in a gap of the high refractive index material in FIG. 9C and on the sensor wafer excluding the pixel regions. FIG. 9E is a sectional view illustrating a state in which a cover glass wafer is attached onto a microlens member in FIG. 9D. FIG. 9F is a sectional view illustrating a state in which a structure in FIG. 9E is divided to manufacture a plurality of solid-state image pickup apparatuses.

First, a manufacturer prepares a sensor wafer 8′ where a photodiode and a color filter are formed on each of the light receiving portions 21 as shown in FIG. 9A.

Subsequently, the manufacturer forms a film of a high refractive index material 9′, such as silicon nitride (Si₃N₄), tantalum pentoxide (Ta₂O₅), or diamond, on an entire surface of the sensor wafer 8′ in a process of laminating a first photorefractive material in a process of laminating a microlens member as shown in FIG. 9B. The film of the high refractive index material 9′ can be formed by chemical vapor deposition (CVD), without being limited thereto.

Subsequently, the manufacturer processes the high refractive index material 9 such that patterns each having a concentric shape are formed on the light receiving portions 21, and removes the high refractive index material from the portion excluding the pixel region 3 in a process of forming a circular shape in the process of laminating a microlens member as shown in FIG. 9C. The high refractive index material 9 can be processed preferably by photolithography and dry etching, without being limited thereto.

The manufacturer then applies the optically transparent low refractive index resin 10 on the entire surface of the sensor wafer 8′ on which the high refractive index material 9 is patterned by spin coating, printing using a squeegee or the like in a process of forming a diffractive lens in the process of laminating a microlens member as shown in FIG. 9D. The low refractive index resin 10 fills the gap of the patterned high refractive index material 9 to form the diffractive lenses 18 in the pixel region 3. The low refractive index resin 10 is also applied on the region outside the pixel region 3, that is, the region on the peripheral circuits 4. The microlens member 25 is thereby formed.

Subsequently, the manufacturer attaches the cover glass wafer 6′ to the microlens member 25 such that the cover glass wafer 6′ is bonded to at least a portion of the microlens member 25, more specifically, to the entire surface in a process of attaching a transparent member as shown in FIG. 9E. It is preferable to bond the cover glass wafer 6′ to the microlens member 25 in a vacuum in order to prevent air bubbles from being formed between bonded surfaces.

Lastly, the manufacturer divides the structure shown in FIG. 9E by dicing to obtain the separate solid-state image pickup apparatuses 7 as shown FIG. 9F.

Although the diffractive lens 18 obtained by patterning the high refractive index material 9 in a concentric shape is used as the microlens in the present embodiment, a Fresnel lens may be used instead of the diffractive lens 18. In this case, the Fresnel lens made of the high refractive index material 9 is formed on each of the light receiving portions 21 of the solid-state image pickup device 8, and an optical adhesive having a low refractive index is filled in another region to form a Fresnel lens layer. The cover glass is bonded to an entire surface of the Fresnel lens layer. The solid-state image pickup apparatus 7 is thereby formed. With such a configuration, since the light receiving portions 21 are sealed, water or particles do not enter the light receiving portions 21, thereby improving product yield and reliability.

In a case where the light receiving portions 21 are lower than the peripheral region in the solid-state image pickup device 8, a same method as that in the first embodiment may be used. That is, a layer of the high refractive index material 9 as the material of the diffractive lens 18 may be left on the region around the pixel region 3 to ensure the height of the peripheral region.

As described above, in the present embodiment, the microlens member 25 having the diffractive lenses 18 is interposed between the solid-state image pickup device 8 and the cover glass 6.

Accordingly, the microlens effect is ensured by the microlens member 25 even when the cover glass 6 is directly attached to the microlens member 25 without forming an air gap. It is therefore not necessary to separately perform the process of forming a spacer, and the manufacturing processes are simplified.

Furthermore, since the microlens member 25 is filled in the entire surface between the solid-state image pickup device 8 and the cover glass 6, water or particles do not enter the light receiving portions 21, thereby improving the product yield.

The region on the peripheral circuits 4 of the solid-state image pickup device 8 is also included in the region where the cover glass 6 is bonded to the microlens member 25. The region on the peripheral circuits 4 has a large bonding area. Thus, even when the solid-state image pickup apparatus 7 is reduced in size, a sufficient bonding strength of the cover glass 6 to the microlens member 25 is obtained, thereby improving the reliability.

Accordingly, the solid-state image pickup apparatus having a configuration capable of maintaining the microlens effect on the pixel region without using a spacer, and the method of manufacturing the solid-state image pickup apparatus can be provided.

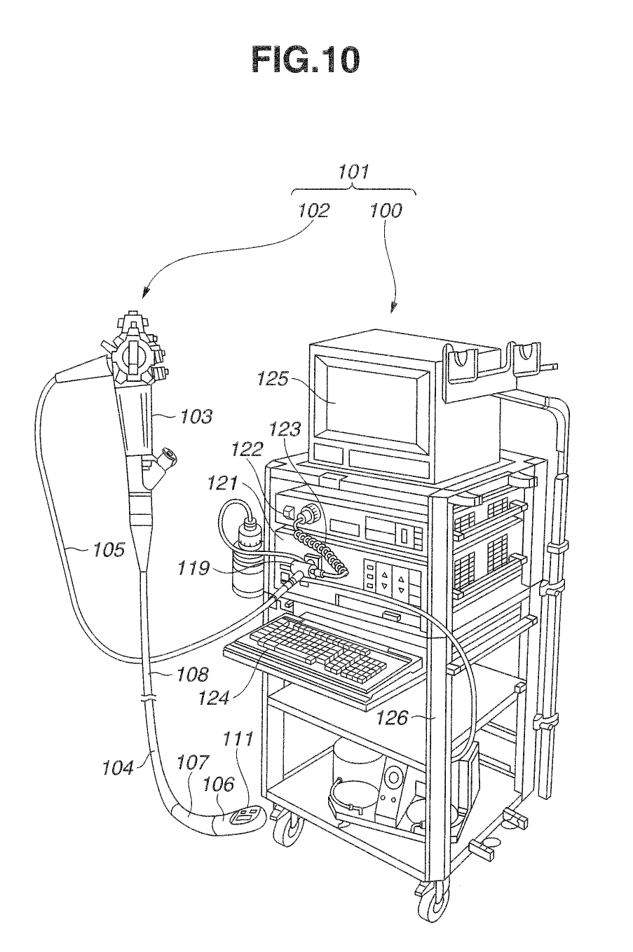

The solid-state image pickup apparatus described in the aforementioned first and second embodiments is provided in an endoscope, for example. FIG. 10 is a perspective view illustrating an endoscope apparatus including an endoscope in which the solid-state image pickup apparatus is provided.

As shown in FIG. 10, an endoscope apparatus 101 includes an endoscope 102 and a peripheral device 100. An operation portion 103, an insertion portion 104, and a universal cord 105 constitute a main portion of the endoscope 102.

A light source device 121, a video processor 122, a connection cable 123, a keyboard 124, and a monitor 125 arranged on a rack 126 constitute a main portion of the peripheral device 100. The endoscope 102 and the peripheral device 100 configured as described above are connected to each other via a connector 119.

The insertion portion 104 of the endoscope 102 includes a distal end portion 106, a bending portion 107, and a flexible tube portion 108.

An objective lens 111 is arranged on a side surface of the distal end portion 106. The solid-state image pickup apparatus 1 or 7 described above is incorporated in the distal end portion 106.

The connector 119 is provided at a distal end of the universal cord 105 of the endoscope 102. The connector 119 is connected to the light source device 121 of the peripheral device 100. An unillustrated light guide ferrule constituting an end portion of an unillustrated light guide, an electrical contact portion to which an end portion of an unillustrated image pickup cable is connected, and the like are arranged at the connector 119.

The image pickup cable is inserted through the insertion portion 104, the operation portion 103, and the universal cord 105 from the solid-state image pickup device in the distal end portion 106 to reach the electrical contact portion in the connector 119, and transmits an electric signal of an image picked up by the solid-state image pickup device to the video processor 122.

Since the solid-state image pickup apparatus described in the first and second embodiments is formed in a small size as described above, the distal end portion of the insertion portion of the endoscope can be reduced in diameter by providing the solid-state image pickup apparatus in the distal end portion.

Furthermore, the solid-state image pickup apparatus described in the embodiments may be provided in a medical capsule endoscope. The solid-state image pickup apparatus may be provided not only in the endoscope, but also in a camera-equipped cell phone and a digital camera.

As described above, in another embodiment of the present invention, the endoscope or the endoscope apparatus includes the insertion portion where the solid-state image pickup apparatus having the solid-state image pickup device, the microlens member laminated on the solid-state image pickup device, and the flat plate-like transparent member attached onto at least a portion of the microlens member as viewed in a planar manner from above the microlens member to seal the pixel region of the solid-state image pickup device is arranged at the distal end portion, the operation portion, and the universal cord.

Having described the preferred embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A solid-state image pickup apparatus comprising:
a solid-state image pickup device;
a microlens member laminated on the solid-state image pickup device; and
a flat plate-like transparent member attached onto at least a portion of the microlens member as viewed in a planar manner from above the microlens member to seal a pixel region of the solid-state image pickup device.

2. The solid-state image pickup apparatus according to claim 1,
wherein the microlens member is made of a transparent resin material.

3. The solid-state image pickup apparatus according to claim 2,
wherein the microlens member includes a first part provided on the pixel region and a second part provided on a region excluding the pixel region, and the first part is formed in a lens shape and is formed lower than the second part toward the solid-state image pickup device.

4. The solid-state image pickup apparatus according to claim 3,
wherein the transparent member is bonded onto the second part of the microlens member, and a gap is formed between the transparent member and the solid-state image pickup device in the pixel region.

5. The solid-state image pickup apparatus according to claim 4,
wherein a peripheral circuit of the solid-state image pickup device is formed on the region excluding the pixel region of the solid-state image pickup device, and
the transparent member is bonded onto a region to overlap the peripheral circuit as viewed in a planar manner from above the microlens member.

6. The solid-state image pickup apparatus according to claim 1,
wherein the microlens member is formed as a diffractive lens layer where a first photorefractive material is formed in a circular shape as viewed in a planar manner from above in the pixel region and a second photorefractive material having a lower refractive index than the first photorefractive material is filled in a gap of the first photorefractive material formed in the circular shape and a region excluding the pixel region, and
the transparent member is bonded onto an entire surface of the diffractive lens layer.

7. The solid-state image pickup apparatus according to claim 6,
wherein a peripheral circuit of the solid-state image pickup device is formed on the region excluding the pixel region of the solid-state image pickup device, and
the transparent member is bonded onto a region to overlap the peripheral circuit as viewed in a planar manner from above the microlens member.

8. The solid-state image pickup apparatus according to claim 1,
wherein the microlens member is formed as a Fresnel lens layer made of a first photorefractive material, and
the transparent member is bonded onto an entire surface of the Fresnel lens layer.

9. The solid-state image pickup apparatus according to claim 8,
wherein a peripheral circuit of the solid-state image pickup device is formed on a region excluding the pixel region of the solid-state image pickup device, and
the transparent member is bonded onto a region to overlap the peripheral circuit as viewed in a planar manner from above the microlens member.

10. A method of manufacturing a solid-state image pickup apparatus, comprising:
a microlens member laminating process of laminating a microlens member on a solid-state image pickup device; and
a transparent member attaching process of attaching a flat plate-like transparent member that seals a pixel region of the solid-state image pickup device onto the microlens member such that the transparent member is bonded onto at least a portion of the microlens member as viewed in a planar manner from above.

11. The method of manufacturing a solid-state image pickup apparatus according to claim 10, further comprising:
a lens-shaped portion forming process of forming the pixel region of the microlens member into a lens shape and forming a portion formed into the lens shape to be lower than a region excluding the pixel region toward the solid-state image pickup device between the microlens member laminating process and the transparent member attaching process, wherein
in the transparent member attaching process, the transparent member is bonded onto the region excluding the pixel region on the microlens member such that a gap generated in the lens-shaped portion forming process is formed between the transparent member and the solid-state image pickup device in the pixel region.

12. The method of manufacturing a solid-state image pickup apparatus according to claim 10,
wherein the microlens member laminating process comprises:
a first photorefractive material laminating process of laminating a first photorefractive material on the solid-state image pickup device,
a circular shape forming process of forming the pixel region of the first photorefractive material into a circular shape as viewed in a planar manner from above, and
a diffractive lens forming process of providing a second photorefractive material having a lower refractive index than the first photorefractive material over an entire surface of the solid-state image pickup device having a gap of the first photorefractive material formed into the circular shape, and forming a diffractive lens layer on the solid-state image pickup device, and
the transparent member attaching process is performed by bonding the transparent member onto an entire surface of the diffractive lens layer.

13. A solid-state image pickup apparatus comprising:
a solid-state image pickup device having a pixel region and a peripheral region excluding the pixel region on which a peripheral circuit is formed;
a microlens member laminated on the solid-state image pickup device and having a microlens-shaped portion on the pixel region and a flat plate-like portion on the peripheral region, the microlens-shaped portion and the flat plate-like portion being made of a same transparent resin material, and the microlens-shaped portion being lower in height than the flat plate-like portion; and
a flat plate-like transparent member attached onto the peripheral region of the microlens member as viewed in a planar manner from above the microlens member to seal the pixel region of the solid-state image pickup device.
